(19) United States
(12) Patent Application Publication
(10) Pub. No.: US 2026/0262193 A1
(43) Pub. Date: Sep. 3, 2026

(54) LIQUID-FLOW COOLING DEVICE

(71) Applicant: COOLER MASTER CO., LTD., Taipei City (TW)

(72) Inventors: Stefan POPESKU, Taipei City (TW); Shang-Ting HUANG, Taipei City (TW)

(73) Assignee: COOLER MASTER CO., LTD., Taipei City (TW)

(21) Appl. No.: 19/555,304

(22) Filed: Mar. 3, 2026

(30) Foreign Application Priority Data
Mar. 3, 2025 (TW) 114202101

(51) Int. Cl. H05K 7/20; F04D 1/04; F04D 29/42

(52) U.S. Cl. CPC H05K 7/20272; F04D 1/04; F04D 29/426; H05K 7/20254; H05K 7/20263

(57) ABSTRACT

Liquid-flow cooling device for cooling heat source comprises pump body comprising pump housing with a liquid flow chamber and impeller rotatably located therein, and water-cooling head fitted to pump housing and having heat exchange chamber and thermal contact face. Heat exchange chamber is connected to liquid flow chamber of pump housing, and thermal contact face faces away from heat exchange chamber. Axis of impeller is perpendicular to a normal to the thermal contact face. Water-cooling head comprises multiple cooling fins in heat exchange chamber. Cooling fins comprise multiple densely distributed cooling fins arranged side by side adjacently to each other and multiple sparsely distributed cooling fins arranged side by side adjacently to each other. Densely distributed cooling fins located at one side of sparsely distributed cooling fins. Interval between any two adjacent densely distributed cooling fins is smaller than interval between any two adjacent sparsely distributed cooling fins.

This application claim priority from Taiwan Patent App. No. 114202101, filed March 3, 2025, the content of which (including all attachments filed therewith) is hereby incorporated by reference in its entirety.

### TECHNICAL FIELD

The present disclosure relates to a cooling device, in particular to a liquid-flow cooling device.

### BACKGROUND OF THE DISCLOSURE

During computer operation, heat sources inside the computer, such as the central processing unit, will generate heat due to high-speed operations. Thus, the computer must be fitted with a cooling device, to quickly and effectively carry away the heat generated by the heat sources, and keep the temperature of the heat sources within a design range specified by the manufacturer. Cooling devices are generally divided into air cooling and liquid cooling types. An air cooling device comprises cooling fins installed on the heat source and a fan installed in the computer, so that heat generated by the heat source is carried away by an airflow generated by the fan. However, fans produce noise during operation, and struggle to cool heat sources that generate a large amount of heat, such as processors of computers used for esports. Therefore, at present, computers used for esports generally use liquid cooling. A liquid cooling device comprises a water cooling head and a radiator installed in the computer, the water cooling head being in thermal contact with the heat source, and connected to the radiator via flow tubes. Under the driving action of a pump fitted to the water cooling head, heat-absorbing cooling liquid can be driven to flow from the water cooling head to the radiator, and then back to the water cooling head from the radiator after dissipating heat in the radiator.

However, in known liquid cooling devices, since an impeller of the pump is configured horizontally with respect to the water cooling head, a flow path connected between a pump chamber and a water cooling head chamber needs to have multiple turning points in order to guide the cooling liquid from the pump chamber to the water cooling head chamber. As a result, the cooling liquid experiences a considerable pressure loss while flowing through, and this has an impact on the efficiency of cooling of the heat source.

### SUMMARY OF THE DISCLOSURE

Exemplary embodiments of the present disclosure provide a liquid-flow cooling device, which may, but is not required to, address at least some problem in convention designs such as where the flow path connected between the pump chamber and the water cooling head chamber has multiple turning points, causing the cooling liquid to experience a considerable pressure loss while flowing through, which impacts the cooling efficiency.

A liquid-flow cooling device according to an example embodiment of the present disclosure can be used to cool a heat source. According to example implementations of disclosed example embodiments, a liquid-flow cooling device can comprise a pump body and a water cooling head. The pump body can comprise a pump housing and an impeller, the pump housing having a liquid flow chamber, and the impeller being rotatably located in the liquid flow chamber. The water cooling head can be fitted to the pump housing, and can have a heat exchange chamber and a thermal contact face. The heat exchange chamber can be connected to the liquid flow chamber of the pump housing, and the thermal contact face can be configured to face away from the heat exchange chamber. An axis of the impeller can be perpendicular to a normal to the thermal contact face. The water cooling head can comprise multiple cooling fins located in the heat exchange chamber. The cooling fins can comprise multiple densely distributed cooling fins and multiple sparsely distributed cooling fins, the densely distributed cooling fins can be located at one side of the sparsely distributed cooling fins. The densely distributed cooling fins can be arranged side by side adjacently to each other, the sparsely distributed cooling fins can be arranged side by side adjacently to each other, and an interval between any two adjacent densely distributed cooling fins can be smaller than an interval between any two adjacent sparsely distributed cooling fins.

A liquid-flow cooling device according to another example embodiment of the present disclosure can be used to cool a heat source. According to example implementations of disclosed example embodiments, a liquid-flow cooling device can comprise a pump body and a water cooling head. The pump body can comprise a pump housing and an impeller, the pump housing having a liquid flow chamber, and the impeller being rotatably located in the liquid flow chamber. The water cooling head can be fitted to the pump housing, and can have a heat exchange chamber and a thermal contact face. The heat exchange chamber can be connected to the liquid flow chamber of the pump housing, and the thermal contact face can be configured to face away from the heat exchange chamber. An axis of the impeller can be perpendicular to a normal to the thermal contact face. The water cooling head can comprise a thermally conductive member and a cover body, the cover body can be joined to the thermally conductive member to jointly enclose the heat exchange chamber. The thermal contact face can be located at a side of the thermally conductive member that is remote from the cover body. The cover body can have an inflow connecting structure, the inflow connecting structure connecting the heat exchange chamber to the liquid flow chamber, and the inflow connecting structure can be an array-type multi-hole structure.

In the liquid-flow cooling device disclosed in accordance with example implementations of the disclosed example embodiments, as a result of having the impeller configured vertically with respect to the water cooling head such that the axis of the impeller is perpendicular to the normal to the thermal contact face of the water cooling head, in the course of rotating, the impeller can drive cooling liquid to flow around the axis of the impeller, and the cooling liquid can enter the heat exchange chamber of the water cooling head directly in the direction of a tangent at the outlet of the liquid flow chamber. Thus, for example and without limitation, the cooling liquid need not experience multiple changes of direction in the process of flowing from the liquid flow chamber to the heat exchange chamber; in this way, pressure loss due to a tortuous flow path can be avoided, which can facilitate maintaining the flow rate of cooling liquid and thus can facilitate ensuring the cooling efficiency of the liquid-flow cooling device.

In some example implementations of the disclosed example embodiments, the configuration of cooling fins at different densities in different regions corresponding to the thermal contact face can enable the single thermal contact face to have multiple heat transfer surface characteristics, for example and without limitation, to help facilitate mitigating the problem of local hot spot cooling while reducing flow resistance caused by heat transfer surface characteristics.

In some example implementations of the disclosed example embodiments, the configuration of the inflow connecting structure of the cover body as an array-type multi-hole structure can, for example and without limitation, facilitate improving the uniformity of distribution of cooling liquid, reducing the occurrence of local high-temperature hot spots, and can, for example and without limitation, also facilitate improving the cooling liquid flow pattern, so as to, for example and without limitation, facilitate increasing the heat transfer area and reduce noise when cooling liquid enters a narrow opening.

The above description of the summary of the present disclosure and the following description of the example embodiments are intended to illustrate and explain the principles of the present disclosure, and can facilitate further understanding of the appended claims of the present disclosure.

### BRIEF DESCRIPTION OF THE DRAWINGS

A more complete appreciation of the present disclosure and many of the attendant advantages thereof will be readily obtained as the same becomes better understood by reference to the following detailed description when considered in connection with the accompanying drawings, wherein:

FIG. 1 is an illustrative three-dimensional schematic drawing of a frame and a liquid-flow cooling device according to a first example embodiment of the present disclosure.

FIG. 2 is an exploded schematic drawing of a pump body, a liquid entry connector and a liquid exit connector of the liquid-flow cooling device shown in FIG. 1.

FIG. 3 is an exploded schematic drawing of a water cooling head of the liquid-flow cooling device shown in FIG. 1.

FIG. 4 is a schematic top view of cooling fins of the water cooling head shown in FIG. 3.

FIG. 5 is a sectional schematic drawing of the liquid-flow cooling device shown in FIG. 1.

FIG. 6 is another sectional schematic drawing of the liquid-flow cooling device shown in FIG. 1.

FIG. 7 is an illustrative three-dimensional schematic drawing of a frame and a liquid-flow cooling device according to a second example embodiment of the present disclosure.

FIG. 8 is an exploded schematic drawing of a pump body, a liquid entry connector and a liquid exit connector of the liquid-flow cooling device shown in FIG. 7.

FIG. 9 is an exploded schematic drawing of a water cooling head of the liquid-flow cooling device shown in FIG. 7.

FIG. 10 is a sectional schematic drawing of the liquid-flow cooling device shown in FIG. 7.

FIG. 11 is another sectional schematic drawing of the liquid-flow cooling device shown in FIG. 7.

### DETAILED DESCRIPTION OF EXEMPLARY EMBODIMENTS

Detailed features and advantages of embodiments of the present disclosure are described in detail below in example embodiments, the content of which is sufficient to allow any person skilled in the art to understand and thereby implement the technical content of embodiments of the present disclosure, and any person skilled in the art can easily understand the relevant objectives and advantages of the present disclosure on the basis of the content disclosed herein, the claims and the drawings. The example embodiments below describe the viewpoints of the present disclosure in further detail, but none of these viewpoints limits the scope of the present disclosure. Accordingly, those of ordinary skill in the art will recognize that various changes and modifications of the embodiments described herein can be made without departing from the scope and spirit of the described disclosure. Also, descriptions of well-known functions and constructions are omitted for clarity and conciseness.

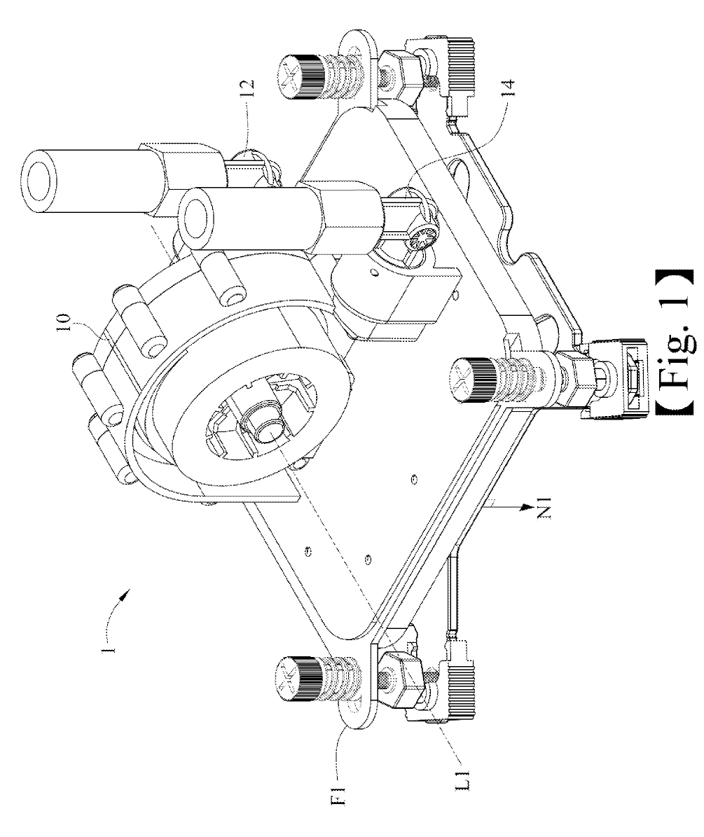

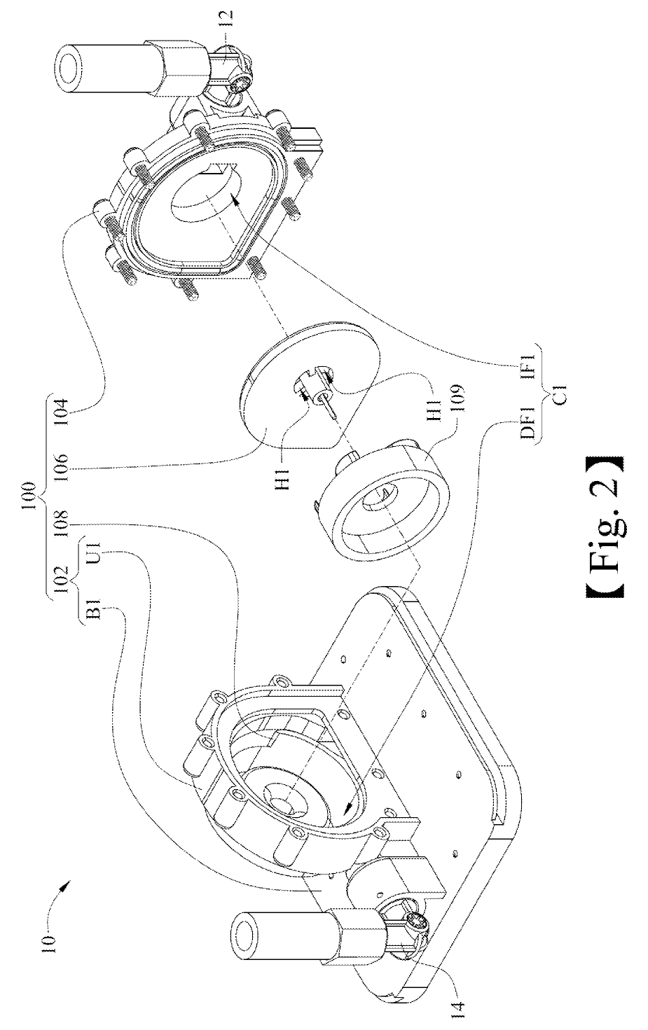

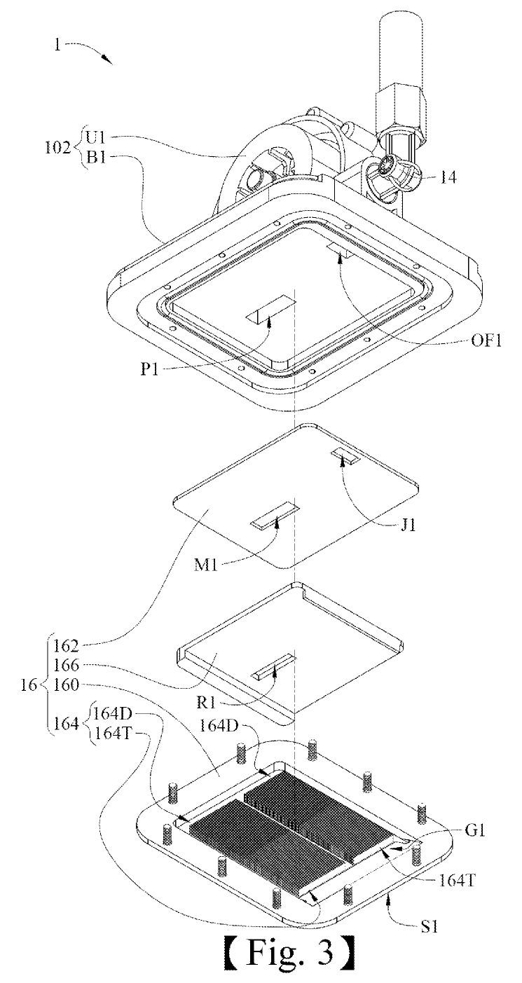

Referring to FIGS. 1 - 3, FIG. 1 is an illustrative three-dimensional schematic drawing of a frame and a liquid-flow cooling device according to a first example embodiment of the present disclosure, FIG. 2 is an exploded schematic drawing of a pump body, a liquid entry connector and a liquid exit connector of the liquid-flow cooling device shown in FIG. 1, and FIG. 3 is an exploded schematic drawing of a water cooling head of the liquid-flow cooling device shown in FIG. 1.

A liquid-flow cooling device 1 according to an example embodiment can be used to cool a heat source (not shown). According to example implementations, the liquid-flow cooling device 1 comprises a pump body 10, a liquid entry connector 12, a liquid exit connector 14 and a water cooling head 16. The pump body 10 is for example locked to a frame F1, and fixed to a motherboard (not shown) via the frame F1.

In example implementations of example embodiments, the pump body 10 comprises a pump housing 100 and an impeller 109; the pump housing 100 has a liquid flow chamber C1 and an outflow chamber OF1, and the impeller 109 is rotatably located in the liquid flow chamber C1.

In example implementations of example embodiments, the pump housing 100 comprises a first casing 102, a second casing 104, an impeller cover 106 and a vortex structure 108. The first casing 102 comprises a base part B1 and an upright part U1. The upright part U1 protrudes from the base part B1, and the second casing 104 is fitted to the upright part U1 of the first casing 102 to jointly enclose the liquid flow chamber C1. The impeller cover 106 is located in the liquid flow chamber C1 and divides the liquid flow chamber C1 into an inflow chamber IF1 and a drive chamber DF1. In addition, the impeller cover 106 has multiple connecting holes H1, and these connecting holes H1 connect the inflow chamber IF1 to the drive chamber DF1, thereby allowing cooling liquid to enter the drive chamber DF1 from the inflow chamber IF1. The impeller 109 is rotatably located in the drive chamber DF1.

In example implementations of example embodiments, the liquid entry connector 12 and the liquid exit connector 14 are respectively located at adjacent sides of the pump body 10, wherein the liquid entry connector 12 is connected to the inflow chamber IF1 in the liquid flow chamber C1, and the liquid exit connector 14 is connected to the outflow chamber OF1 of the pump housing 100. The liquid entry connector 12 is used to guide cooling liquid from the outside into the inflow chamber IF1, and the liquid exit connector 14 is used to guide cooling liquid out of the outflow chamber OF1. In an example embodiment, the liquid entry connector 12 is arranged on the second casing 104 of the pump housing 100.

In example implementations of example embodiments, the water cooling head 16 is fitted to the base part B1 of the first casing 102 of the pump housing 100, and the water cooling head 16 has a heat exchange chamber G1 and a thermal contact face S1. The heat exchange chamber G1 is connected to the liquid flow chamber C1 of the pump housing 100, and the thermal contact face S1 faces away from the heat exchange chamber G1. The first casing 102 of the pump housing 100 has a connecting path P1 extending from the base part B1 to the upright part U1, and two opposite ends of the connecting path P1 are respectively connected to the liquid flow chamber C1 and the heat exchange chamber G1.

In example implementations of example embodiments, the water cooling head 16 comprises a thermally conductive member 160, a cover body 162, multiple cooling fins 164 and a flow-blocking member 166, the cover body 162 being joined to the thermally conductive member 160 to jointly enclose the heat exchange chamber G1. In addition, the thermal contact face S1 is located on a side of the thermally conductive member 160 that is remote from the cover body 162. The cover body 162 has an inflow connecting structure M1 and an outflow connecting structure J1, wherein the inflow connecting structure M1 connects the heat exchange chamber G1 to the drive chamber DF1 in the liquid flow chamber C1 of the pump housing 100, and the outflow connecting structure J1 connects the heat exchange chamber G1 to the outflow chamber OF1 of the pump housing 100. The inflow connecting structure M1 is connected to the drive chamber DF1 via the connecting path P1. In an example embodiment, the inflow connecting structure M1 of the cover body 162 is a single opening structure, and the outflow connecting structure J1 is also a single opening structure, but the present disclosure is not limited to such example implementations. For example, in some example embodiments, the inflow connecting structure may be an array-type multi-hole structure.

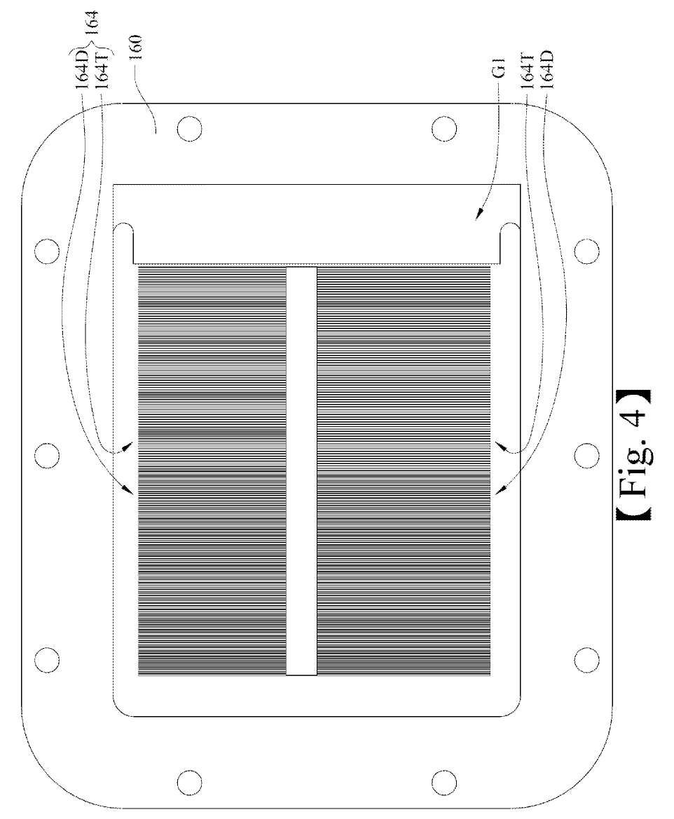

Referring to FIGS. 3 and 4 together, FIG. 4 is a schematic top view of the cooling fins of the water cooling head shown in FIG. 3. In example implementations of example embodiments, the cooling fins 164 are arranged on the thermally conductive member 160 and located in the heat exchange chamber G1. In an example embodiment, the cooling fins 164 comprise multiple densely distributed cooling fins 164D and multiple sparsely distributed cooling fins 164T, the densely distributed cooling fins 164D being located at one side of the sparsely distributed cooling fins 164T. The densely distributed cooling fins 164D are arranged side by side adjacently to each other, the sparsely distributed cooling fins 164T are arranged side by side adjacently to each other, and an interval between any two adjacent densely distributed cooling fins 164D is smaller than an interval between any two adjacent sparsely distributed cooling fins 164T. Thus, the configuration of cooling fins at different densities in different regions corresponding to the thermal contact face enables the single thermal contact face to have multiple heat transfer surface characteristics, for mitigating the problem of local hot spot cooling while reducing flow resistance caused by heat transfer surface characteristics. For example, if the layout position of a local high-temperature hot spot and the corresponding thermal contact face region are known, a denser distribution of cooling fins can be designed in that region, and a thinner distribution of cooling fins can be configured at other positions. In an example embodiment, the cooling fins 164 are all of the same thickness, for example. However, the present disclosure is not limited to such example implementations. In other example embodiments, the cooling fins of the water cooling head may have identical and uniform fin separation. In addition, in some embodiments, the cooling fins may be of different thicknesses.

In example implementations of example embodiments, the flow-blocking member 166 is located in the heat exchange chamber G1 and sandwiched between the cooling fins 164 and the cover body 162. The flow-blocking member 166 has an opening R1; the opening R1 corresponds to the inflow connecting structure M1 of the cover body 162, and the opening R1 exposes some of the cooling fins 164.

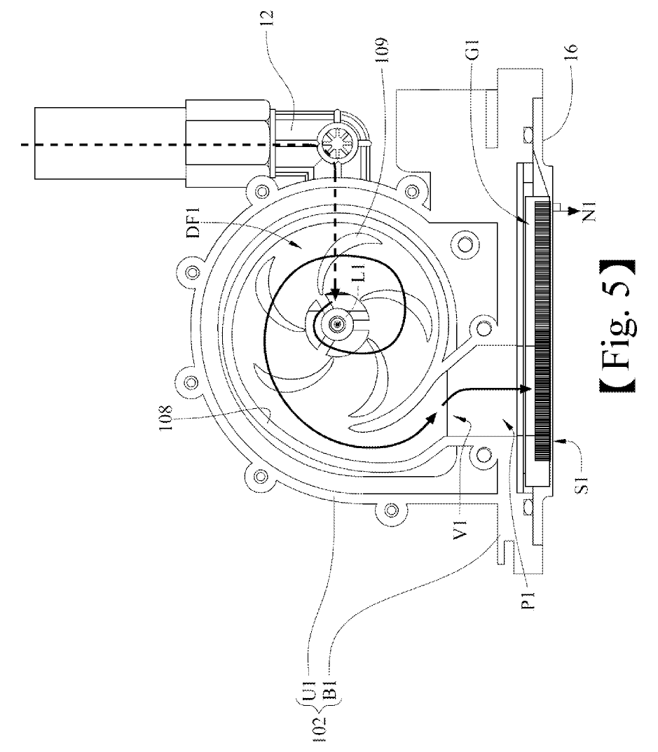

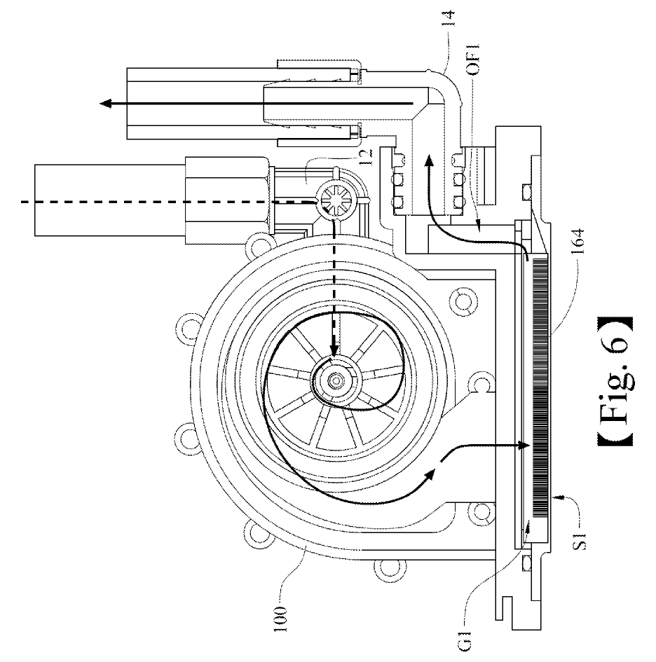

Referring to FIGS. 5 and 6, FIG. 5 is a sectional schematic drawing of the liquid-flow cooling device shown in FIG. 1, and FIG. 6 is another sectional schematic drawing of the liquid-flow cooling device shown in FIG. 1.

In example implementations of example embodiments, the vortex structure 108 of the pump housing 100 is located in the drive chamber DF1 and encloses a vortex channel, and an outlet V1 of the vortex channel is connected to the connecting path P1. The impeller 109 is located at the center of the vortex channel, and an axis L1 of the impeller 109 is perpendicular to a normal N1 to the thermal contact face S1 of the water cooling head 16. In an example embodiment, the vortex structure 108 is arranged on the upright part U1 of the first casing 102, but the present disclosure is not limited such example implementations. In other example embodiments, the vortex structure may be arranged on the impeller cover.

In example implementations of example embodiments, as a result of having the impeller 109 configured vertically with respect to the water cooling head 16 such that the axis L1 of the impeller 109 is perpendicular to the normal N1 to the thermal contact face S1 of the water cooling head 16, in the course of rotating, the impeller 109 can drive cooling liquid to flow inside the drive chamber DF1 along the vortex channel around the axis L1 of the impeller 109, and upon reaching the outlet V1 of the vortex channel, the cooling liquid can finally enter the heat exchange chamber G1 of the water cooling head 16 directly via the connecting path P1, in the direction of a tangent to the vortex structure 108 at the outlet V1. That is to say, since the impeller 109 is configured with its axis L1 perpendicular to the normal N1 to the thermal contact face S1 of the water cooling head 16, the outlet V1 of the vortex channel can essentially be provided facing toward the water cooling head 16, so cooling liquid need not experience multiple changes of direction in the process of flowing out of the outlet V1 of the vortex channel to the heat exchange chamber G1. In this way, for example and without limitation, pressure loss due to a tortuous flow path can be avoided, for example and without limitation, to facilitate maintaining the flow rate of cooling liquid and thus, for example and without limitation, to facilitate ensuring the cooling efficiency of the liquid-flow cooling device 1.

In example implementations of example embodiments, as shown in FIGS. 3, 5 and 6, the cooling liquid sequentially passes through the inflow connecting structure M1 of the cover body 162 and the opening R1 of the flow-blocking member 166 and flows into gaps between the cooling fins 164, so as to absorb heat of the cooling fins 164. Finally, the cooling liquid leaves the heat exchange chamber G1 via the outflow connecting structure J1 of the cover body 162 and flows to the outflow chamber OF1 of the pump housing 100, and is guided out of the outflow chamber OF1 through the liquid exit connector 14.

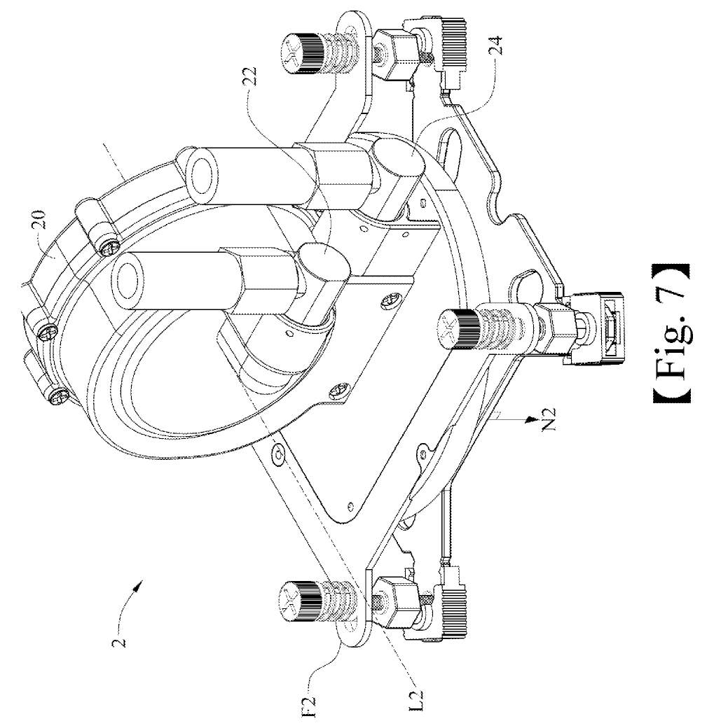

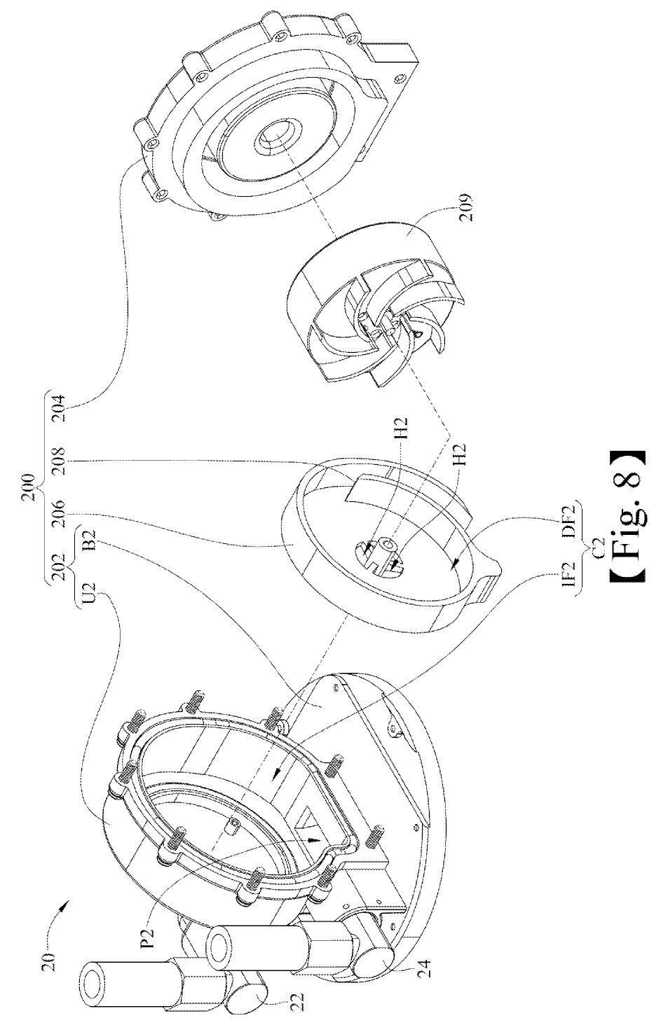

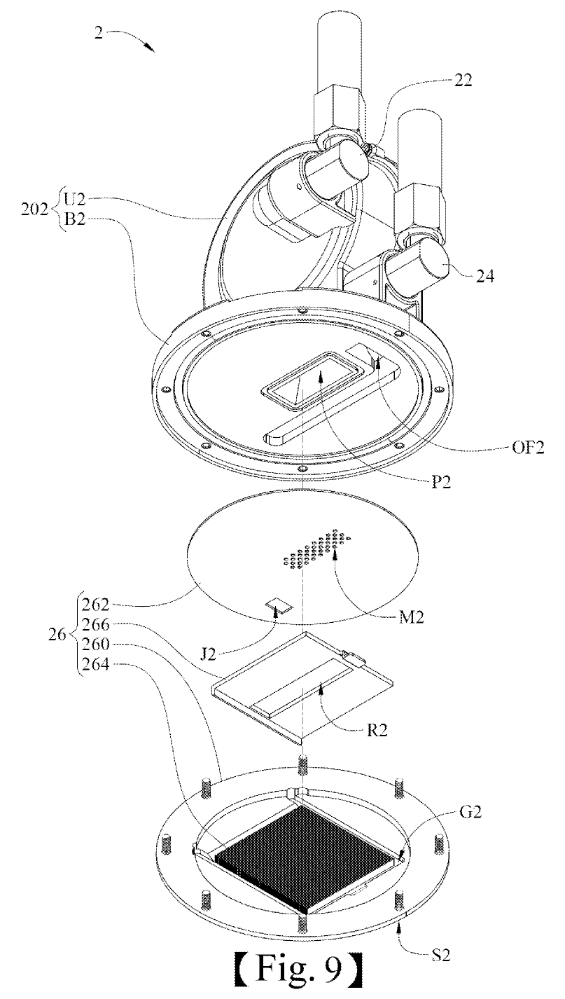

Referring to FIGS. 7 - 9, FIG. 7 is an illustrative three-dimensional schematic drawing of a frame and a liquid-flow cooling device according to a second example embodiment of the present disclosure, FIG. 8 is an exploded schematic drawing of a pump body, a liquid entry connector and a liquid exit connector of the liquid-flow cooling device shown in FIG. 7, and FIG. 9 is an exploded schematic drawing of a water cooling head of the liquid-flow cooling device shown in FIG. 7.

A liquid-flow cooling device 2 in this example embodiment can be used to cool a heat source (not shown). The liquid-flow cooling device 2 comprises a pump body 20, a liquid entry connector 22, a liquid exit connector 24 and a water cooling head 26. The pump body 20 is for example locked to a frame F2, and fixed to a motherboard (not shown) via the frame F2.

In example implementations of example embodiments, the pump body 20 comprises a pump housing 200 and an impeller 209; the pump housing 200 has a liquid flow chamber C2 and an outflow chamber OF2, and the impeller 209 is rotatably located in the liquid flow chamber C2.

In example implementations of example embodiments, the pump housing 200 comprises a first casing 202, a second casing 204, an impeller cover 206 and a vortex structure 208. The first casing 202 comprises a base part B2 and an upright part U2. The upright part U2 protrudes from the base part B2, and the second casing 204 is fitted to the upright part U2 of the first casing 202 to jointly enclose the liquid flow chamber C2. The impeller cover 206 is located in the liquid flow chamber C2 and divides the liquid flow chamber C2 into an inflow chamber IF2 and a drive chamber DF2. In addition, the impeller cover 206 has multiple connecting holes H2, and these connecting holes H2 connect the inflow chamber IF2 to the drive chamber DF2, thereby allowing cooling liquid to enter the drive chamber DF2 from the inflow chamber IF2. The impeller 209 is rotatably located in the drive chamber DF2.

In example implementations of example embodiments, the liquid entry connector 22 and the liquid exit connector 24 are respectively located at adjacent sides of the pump body 20, wherein the liquid entry connector 22 is connected to the inflow chamber IF2 in the liquid flow chamber C2, and the liquid exit connector 24 is connected to the outflow chamber OF2 of the pump housing 200. The liquid entry connector 22 is used to guide cooling liquid from the outside into the inflow chamber IF2, and the liquid exit connector 24 is used to guide cooling liquid out of the outflow chamber OF2. In the second example embodiment, the liquid entry connector 22 is arranged on the upright part U2 of the first casing 202 of the pump housing 200.

In example implementations of example embodiments, the water cooling head 26 is fitted to the base part B2 of the first casing 202 of the pump housing 200, and the water cooling head 26 has a heat exchange chamber G2 and a thermal contact face S2. The heat exchange chamber G2 is connected to the liquid flow chamber C2 of the pump housing 200, and the thermal contact face S2 faces away from the heat exchange chamber G2. The first casing 202 of the pump housing 200 has a connecting path P2 extending from the base part B2 to the upright part U2, and two opposite ends of the connecting path P2 are respectively connected to the liquid flow chamber C2 and the heat exchange chamber G2.

In example implementations of example embodiments, the water cooling head 26 comprises a thermally conductive member 260, a cover body 262, multiple cooling fins 264 and a flow-blocking member 266, the cover body 262 being joined to the thermally conductive member 260 to jointly enclose the heat exchange chamber G2. In addition, the thermal contact face S2 is located on a side of the thermally conductive member 260 that is remote from the cover body 262. The cover body 262 has an inflow connecting structure M2 and an outflow connecting structure J2, wherein the inflow connecting structure M2 connects the heat exchange chamber G2 to the drive chamber DF2 in the liquid flow chamber C2 of the pump housing 200, and the outflow connecting structure J2 connects the heat exchange chamber G2 to the outflow chamber OF2 of the pump housing 200. The inflow connecting structure M2 is connected to the drive chamber DF2 via the connecting path P2. In example implementations of the second example embodiment, the inflow connecting structure M2 of the cover body 262 can be an array-type multi-hole structure, which, for example and without limitation, can facilitate improving the uniformity of distribution of cooling liquid, reducing the occurrence of local high-temperature hot spots, and, for example and without limitation, can also facilitate improve the cooling liquid flow pattern, so as to, for example and without limitation, facilitate increasing the heat transfer area and reduce noise when cooling liquid enters a narrow opening.

In example implementations of example embodiments, the cooling fins 264 are arranged on the thermally conductive member 260 and located in the heat exchange chamber G2. The cooling fins 264 are arranged side by side adjacently to each other, and an interval between any two adjacent cooling fins 264 is the same. In addition, the cooling fins 264 are all of the same thickness, for example. However, the present disclosure is not limited to the configuration of the intervals between the cooling fins and the configuration of the cooling fin thickness which are describer above in example implementations.

In example implementations of example embodiments, the flow-blocking member 266 is located in the heat exchange chamber G2 and sandwiched between the cooling fins 264 and the cover body 262. The flow-blocking member 266 has an opening R2; the opening R2 corresponds to the inflow connecting structure M2 of the cover body 262, and the opening R2 exposes some of the cooling fins 264.

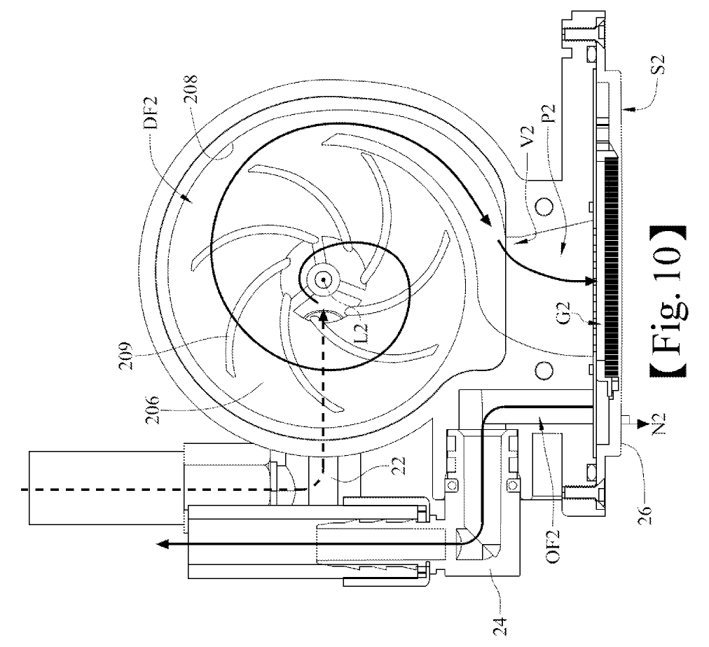

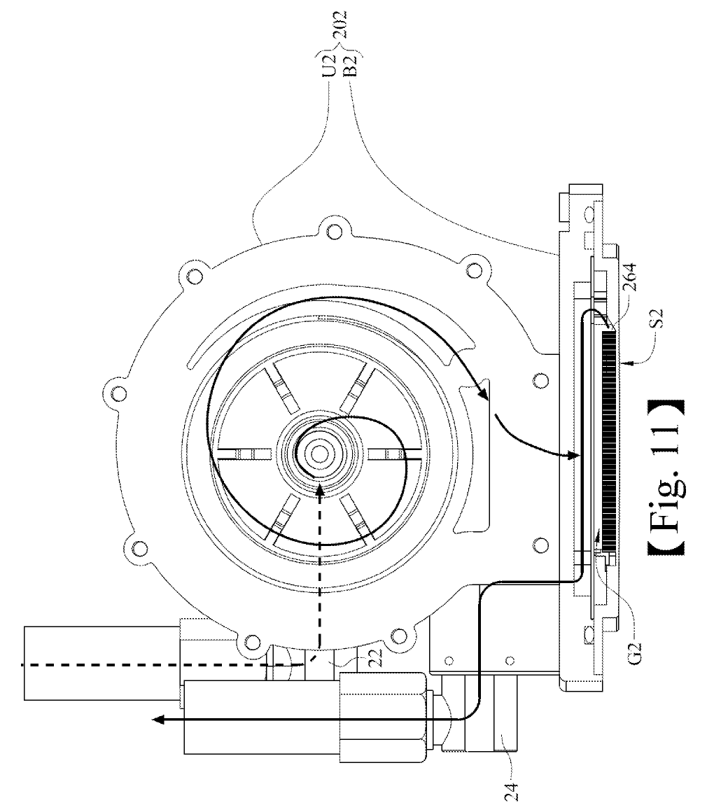

Referring to FIGS. 10 and 11, FIG. 10 is a sectional schematic drawing of the liquid-flow cooling device shown in FIG. 7, and FIG. 11 is another sectional schematic drawing of the liquid-flow cooling device shown in FIG. 7.

In example implementations of example embodiments, the vortex structure 208 of the pump housing 200 is located in the drive chamber DF2 and encloses a vortex channel, and an outlet V2 of the vortex channel is connected to the connecting path P2. The impeller 209 is located at the center of the vortex channel, and an axis L2 of the impeller 209 is perpendicular to a normal N2 to the thermal contact face S2 of the water cooling head 26. In the second example embodiment, the vortex structure 208 is arranged on the impeller cover 206, but the present disclosure is not limited to such example implementations. In other example embodiments, the vortex structure may be arranged on the upright part of the first casing.

In example implementations of example embodiments, as a result of having the impeller 209 configured vertically with respect to the water cooling head 26 such that the axis L2 of the impeller 209 is perpendicular to the normal N2 to the thermal contact face S2 of the water cooling head 26, in the course of rotating, the impeller 209 can drive cooling liquid to flow inside the drive chamber DF2 along the vortex channel around the axis L2 of the impeller 209, and upon reaching the outlet V2 of the vortex channel, the cooling liquid can finally enter the heat exchange chamber G2 of the water cooling head 26 directly via the connecting path P2, in the direction of a tangent to the vortex structure 208 at the outlet V2. Fo example, since the impeller 209 is configured with its axis L2 perpendicular to the normal N2 to the thermal contact face S2 of the water cooling head 26, the outlet V2 of the vortex channel can essentially be provided facing toward the water cooling head 26, so cooling liquid need not experience multiple changes of direction in the process of flowing out of the outlet V2 of the vortex channel to the heat exchange chamber G2. In this way, for example and without limitation, pressure loss due to a tortuous flow path can be avoided, for example and without limitation, to facilitate maintaining the flow rate of cooling liquid and thus, for example and without limitation, to facilitate ensuring the cooling efficiency of the liquid-flow cooling device 2.

Next, according to example implementations of example embodiments, the cooling liquid sequentially passes through the inflow connecting structure M2 of the cover body 262 and the opening R2 of the flow-blocking member 266 and flows into gaps between the cooling fins 264, so as to absorb heat of the cooling fins 264. Finally, the cooling liquid leaves the heat exchange chamber G2 via the outflow connecting structure J2 of the cover body 262 and flows to the outflow chamber OF2 of the pump housing 200, and is guided out of the outflow chamber OF2 through the liquid exit connector 24.

In the liquid-flow cooling device according to the example embodiments described above, as a result of having the impeller configured vertically with respect to the water cooling head such that the axis of the impeller is perpendicular to the normal to the thermal contact face of the water cooling head, in the course of rotating, the impeller can drive cooling liquid to flow around the axis of the impeller, and the cooling liquid can enter the heat exchange chamber of the water cooling head directly in the direction of a tangent at the outlet of the liquid flow chamber. Thus, for example and without limitation, the cooling liquid need not experience multiple changes of direction in the process of flowing from the liquid flow chamber to the heat exchange chamber; in this way, for example and without limitations, pressure loss due to a tortuous flow path can be avoided, in order to maintain the flow rate of cooling liquid and thus ensure the cooling efficiency of the liquid-flow cooling device.

In some example implementations of example embodiments, the configuration of cooling fins at different densities in different regions corresponding to the thermal contact face enables the single thermal contact face to have multiple heat transfer surface characteristics, for example and without limitation, for mitigating the problem of local hot spot cooling while reducing flow resistance caused by heat transfer surface characteristics.

In some example implementations of example embodiments, the configuration of the inflow connecting structure of the cover body as an array-type multi-hole structure can, for example and without limitation, improve the uniformity of distribution of cooling liquid, reducing the occurrence of local high-temperature hot spots, and can also, for example and without limitation, improve the cooling liquid flow pattern, so as to, for example and without limitation, increase the heat transfer area and reduce noise when cooling liquid enters a narrow opening.

The above-presented description and figures are intended by way of example only and are not intended to limit the disclosed illustrative example embodiments in any way except as set forth in the appended claims and full equivalents thereof. It is particularly noted that various technical aspects of the various elements of the various exemplary embodiments that have been described above can be combined in numerous other ways, all of which are considered to be within the scope of the disclosure.

Accordingly, although exemplary implementations of example embodiments have been disclosed, these are not intended to limit the present disclosure, and any person skilled in the art should be able to make changes and modifications without departing from the spirit and scope of the present disclosure. Therefore, the scope of patent protection of the present disclosure shall be as defined by the claims attached hereto and equivalents thereof.

The terms and corresponding labels referenced in the disclosure are listed below for convenience. As would be readily appreciated by skilled artisans in the relevant art, while these and other descriptive terms are used throughout this specification to facilitate understanding, it is not intended to limit any components that can be used in combinations or individually to implement various aspects of the embodiments of the present disclosure.

1, 2: liquid-flow cooling device

10, 20: pump body

12, 22: liquid entry connector

14, 24: liquid exit connector

16, 26: water cooling head

100, 200: pump housing

102, 202: first casing

104, 204: second casing

106, 206: impeller cover

108, 208: vortex structure

109, 209: impeller

160, 260: thermally conductive member

162, 262: cover body

164, 264: cooling fins

164D: densely distributed cooling fins

164T: sparsely distributed cooling fins

166, 266: flow-blocking member

B1, B2: base part

C1, C2: liquid flow chamber

DF1, DF2: drive chamber

F1, F2: frame

G1, G2: heat exchange chamber

H1, H2: connecting hole

IF1, IF2: inflow chamber

J1, J2: outflow connecting structure

L1, L2: axis

M1, M2: inflow connecting structure

N1, N2: normal

OF1, OF2: outflow chamber

P1, P2: connecting path

R1, R2: opening

S1, S2: thermal contact face

U1, U2: upright part

V1, V2: outlet

1. A liquid-flow cooling device for cooling a heat source, the liquid-flow cooling device comprising:
a pump body, comprising a pump housing and an impeller, the pump housing having a liquid flow chamber, and the impeller being rotatably located in the liquid flow chamber; and
a water cooling head fitted to the pump housing, the water cooling head having a heat exchange chamber and a thermal contact face, the heat exchange chamber being connected to the liquid flow chamber, and the thermal contact face facing away from the heat exchange chamber;
wherein an axis of the impeller is perpendicular to a normal to the thermal contact face; and
wherein the water cooling head comprises multiple cooling fins located in the heat exchange chamber, the cooling fins comprising multiple densely distributed cooling fins and multiple sparsely distributed cooling fins, the densely distributed cooling fins being located at one side of the sparsely distributed cooling fins, the densely distributed cooling fins being arranged side by side adjacently to each other, the sparsely distributed cooling fins being arranged side by side adjacently to each other, and an interval between any two adjacent said densely distributed cooling fins being smaller than an interval between any two adjacent said sparsely distributed cooling fins.

2. A liquid-flow cooling device for cooling a heat source, the liquid-flow cooling device comprising:
a pump body, comprising a pump housing and an impeller, the pump housing having a liquid flow chamber, and the impeller being rotatably located in the liquid flow chamber; and
a water cooling head fitted to the pump housing, the water cooling head having a heat exchange chamber and a thermal contact face, the heat exchange chamber being connected to the liquid flow chamber, and the thermal contact face facing away from the heat exchange chamber;
wherein an axis of the impeller is perpendicular to a normal to the thermal contact face; and
wherein the water cooling head comprises a thermally conductive member and a cover body, the cover body being joined to the thermally conductive member to jointly enclose the heat exchange chamber, the thermal contact face being located at a side of the thermally conductive member that is remote from the cover body, the cover body having an inflow connecting structure, the inflow connecting structure connecting the heat exchange chamber to the liquid flow chamber, and the inflow connecting structure being an array-type multi-hole structure.

3. The liquid-flow cooling device as claimed in claim 1, wherein the pump housing comprises a first casing and a second casing, the first casing comprising a base part and an upright part, the upright part protruding from the base part, and the second casing being fitted to the upright part of the first casing to jointly enclose the liquid flow chamber.

4. The liquid-flow cooling device as claimed in claim 3, wherein the pump housing further comprises an impeller cover, the impeller cover being located in the liquid flow chamber and dividing the liquid flow chamber into an inflow chamber and a drive chamber which are connected to each other, and the impeller being rotatably located in the drive chamber.

5. The liquid-flow cooling device as claimed in claim 4, wherein the impeller cover has multiple connecting holes which connect the inflow chamber to the drive chamber.

6. The liquid-flow cooling device as claimed in claim 5, wherein the first casing has a connecting path extending from the base part to the upright part, two opposite ends of the connecting path being respectively connected to the drive chamber and the heat exchange chamber.

7. The liquid-flow cooling device as claimed in claim 6, wherein the pump housing further comprises a vortex structure, the vortex structure being arranged on the upright part and located in the drive chamber, the vortex structure enclosing a vortex channel, the impeller being located at the center of the vortex channel, and an outlet of the vortex channel being connected to the connecting path.

8. The liquid-flow cooling device as claimed in claim 6, wherein the pump housing further comprises a vortex structure, the vortex structure being arranged on the impeller cover and located in the drive chamber, the vortex structure enclosing a vortex channel, the impeller being located at the center of the vortex channel, and an outlet of the vortex channel being connected to the connecting path.

9. The liquid-flow cooling device as claimed in claim 1, wherein the pump housing further has an outflow chamber, and the water cooling head further comprises a thermally conductive member and a cover body, the cover body being joined to the thermally conductive member to jointly enclose the heat exchange chamber, the thermal contact face being located at a side of the thermally conductive member that is remote from the cover body, the cover body having an inflow connecting structure and an outflow connecting structure, the inflow connecting structure connecting the heat exchange chamber to the liquid flow chamber, and the outflow connecting structure connecting the heat exchange chamber to the outflow chamber.

10. The liquid-flow cooling device as claimed in claim 9, wherein the inflow connecting structure is a single opening structure or an array-type multi-hole structure.

11. The liquid-flow cooling device as claimed in claim 2, wherein the pump housing further has an outflow chamber, the cover body further has an outflow connecting structure, and the outflow connecting structure connects the heat exchange chamber to the outflow chamber.

12. The liquid-flow cooling device as claimed in claim 2, wherein the water cooling head further comprises multiple cooling fins, the cooling fins being arranged on the thermally conductive member and located in the heat exchange chamber.

13. The liquid-flow cooling device as claimed in claim 9, wherein the water cooling head further comprises a flow-blocking member located in the heat exchange chamber and sandwiched between the cooling fins and the cover body, the flow-blocking member having an opening corresponding to the inflow connecting structure of the cover body, and the opening exposing some of the cooling fins.

14. The liquid-flow cooling device as claimed in claim 9, further comprising a liquid entry connector and a liquid exit connector, wherein the pump housing comprises a first casing, a second casing and an impeller cover, the first casing comprising a base part and an upright part, the upright part protruding from the base part, the second casing being fitted to the upright part of the first casing to jointly enclose the liquid flow chamber, the impeller cover being located in the liquid flow chamber and dividing the liquid flow chamber into an inflow chamber and a drive chamber which are connected to each other, and the impeller being rotatably located in the drive chamber; the liquid entry connector and the liquid exit connector are respectively located at adjacent sides of the pump body, the liquid entry connector is connected to the inflow chamber, and the liquid exit connector is connected to the outflow chamber.

15. The liquid-flow cooling device as claimed in claim 14, wherein the liquid entry connector is arranged on the upright part of the first casing or the second casing of the pump housing.

16. The liquid-flow cooling device as claimed in claim 2, wherein the pump housing comprises a first casing and a second casing, the first casing comprising a base part and an upright part, the upright part protruding from the base part, and the second casing being fitted to the upright part of the first casing to jointly enclose the liquid flow chamber.

17. The liquid-flow cooling device as claimed in claim 16, wherein the pump housing further comprises an impeller cover, the impeller cover being located in the liquid flow chamber and dividing the liquid flow chamber into an inflow chamber and a drive chamber which are connected to each other, and the impeller being rotatably located in the drive chamber.

18. The liquid-flow cooling device as claimed in claim 17, wherein the impeller cover has multiple connecting holes which connect the inflow chamber to the drive chamber.

19. The liquid-flow cooling device as claimed in claim 18, wherein the first casing has a connecting path extending from the base part to the upright part, two opposite ends of the connecting path being respectively connected to the drive chamber and the heat exchange chamber.

20. The liquid-flow cooling device as claimed in claim 19, wherein the pump housing further comprises a vortex structure, the vortex structure being arranged on the upright part and located in the drive chamber, the vortex structure enclosing a vortex channel, the impeller being located at the center of the vortex channel, and an outlet of the vortex channel being connected to the connecting path.

21. The liquid-flow cooling device as claimed in claim 19, wherein the pump housing further comprises a vortex structure, the vortex structure being arranged on the impeller cover and located in the drive chamber, the vortex structure enclosing a vortex channel, the impeller being located at the center of the vortex channel, and an outlet of the vortex channel being connected to the connecting path.

22. The liquid-flow cooling device as claimed in claim 12, wherein the water cooling head further comprises a flow-blocking member located in the heat exchange chamber and sandwiched between the cooling fins and the cover body, the flow-blocking member having an opening corresponding to the inflow connecting structure of the cover body, and the opening exposing some of the cooling fins.

23. The liquid-flow cooling device as claimed in claim 11, further comprising a liquid entry connector and a liquid exit connector, wherein the pump housing comprises a first casing, a second casing and an impeller cover, the first casing comprising a base part and an upright part, the upright part protruding from the base part, the second casing being fitted to the upright part of the first casing to jointly enclose the liquid flow chamber, the impeller cover being located in the liquid flow chamber and dividing the liquid flow chamber into an inflow chamber and a drive chamber which are connected to each other, and the impeller being rotatably located in the drive chamber; the liquid entry connector and the liquid exit connector are respectively located at adjacent sides of the pump body, the liquid entry connector is connected to the inflow chamber, and the liquid exit connector is connected to the outflow chamber.

24. The liquid-flow cooling device as claimed in claim 23, wherein the liquid entry connector is arranged on the upright part of the first casing or the second casing of the pump housing.
